(19) United States
(12) Patent Application Publication
(10) Pub. No.: US 2009/0273910 A1
(43) Pub. Date: Nov. 5, 2009

(54) Functional Unit And Method For The Production Thereof

(75) Inventors: Jurgen Wolf, Berlin (DE); Kai Zoschke, Berlin (DE); Thorsten Fischer, Ahrensfelde (DE); Michael Topper, Berlin (DE); Herbert Reichl, Berlin (DE)

Correspondence Address: GIBSON & DERNIER L.L.P., 900 ROUTE 9 NORTH, SUITE 504, WOODBRIDGE, NJ, 07095, US

(73) Assignee: FRAUNHOFER-GESELLSCHAFT ZUR FORDERUNG DER ANGEWANDTEN FORSCHUNG E.V., Munchen (DE)

(21) Appl. No.: 12/434,950

(22) Filed: May 4, 2009

Related U.S. Application Data
(60) Provisional application No. 61/050,384, filed on May 5, 2008.

(51) Int. Cl. H05K 1/18; H05K 3/30

(52) U.S. Cl. 361/761; 29/832

(57) ABSTRACT

The present invention relates to a functional unit, containing at least one active or passive electronic component, the functional unit being surrounded by at least one flexible dielectric layer and, on the outer side of the functional unit, contacts are provided for contacting the electrical components for further mounting.

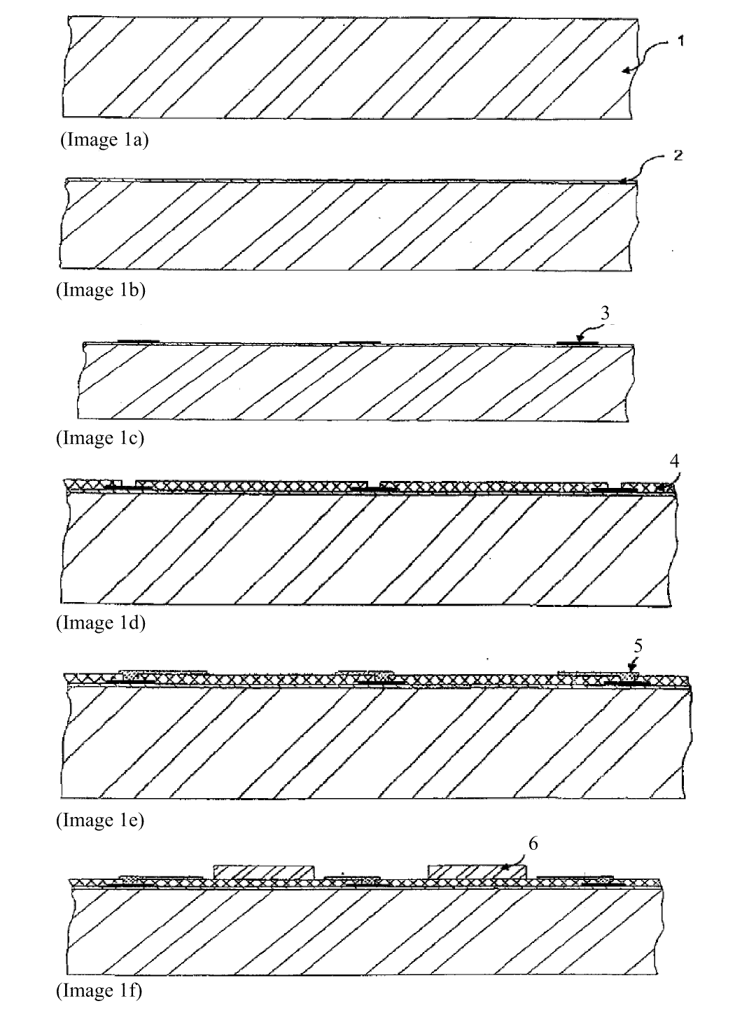

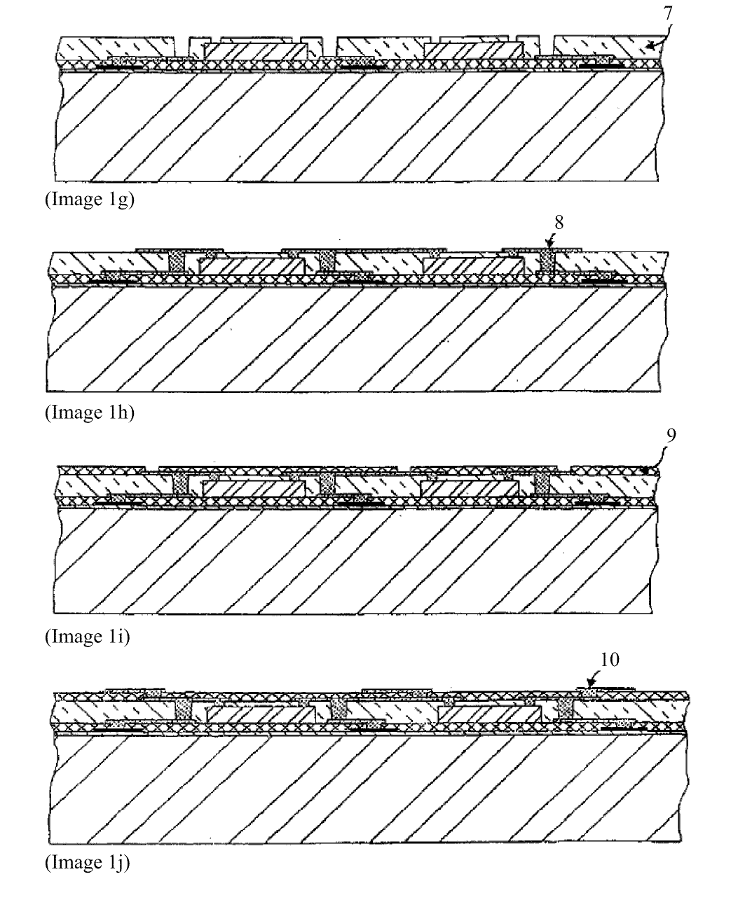

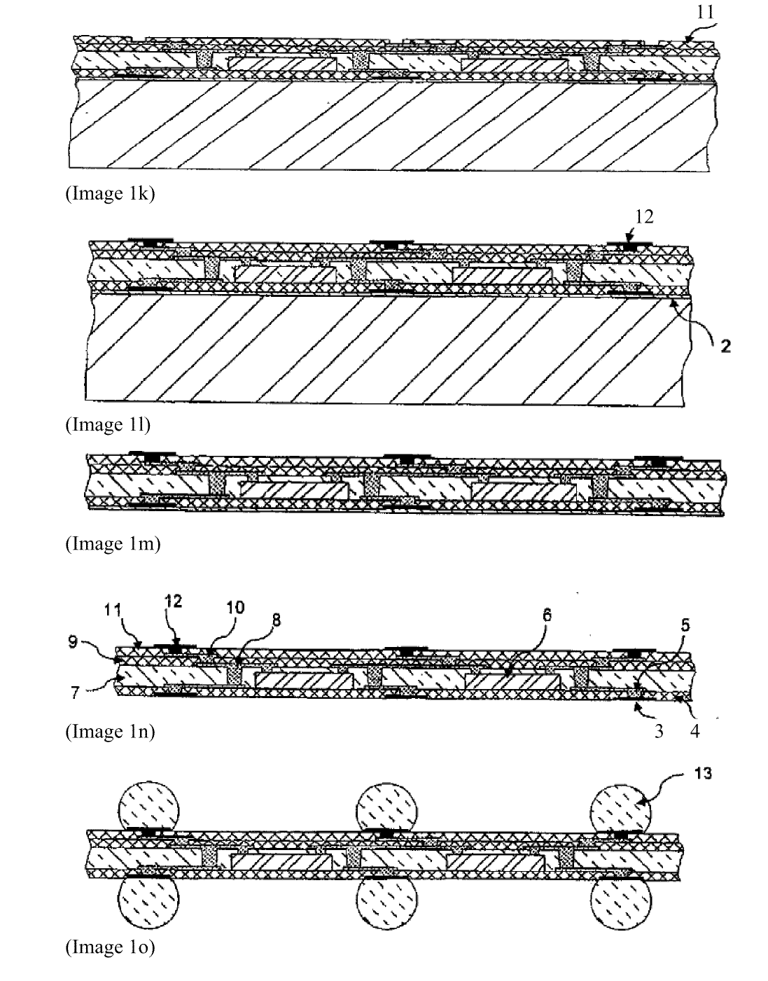

### CROSS REFERENCE TO RELATED APPLICATIONS

This application claims the benefit of U.S. Provisional Patent Application No.: 61/050,384, filed May 5, 2008, the entire disclosure of which is hereby incorporated by reference.

### BACKGROUND

The present invention relates to a functional unit and also to a method for the production thereof.

The aim of mounting and connecting technics for microelectronic components (e.g. unhoused electronic circuits, passive components, SMD etc.) lies in the direction of continuing progressive miniaturisation of complex systems and also in increasing the functionality and reliability. For this purpose, presently unhoused electronic circuits (“IC”=integrated circuit; “bare dies”=unhoused electrical circuit) are mounted directly on the substrate carrier (printed circuit board, silicon, glass) and connected electrically. For this purpose, different contacting methods (wire bonding, flip chip) for the chip on board (COB) are used presently for the contacting of semiconductor components. For mechanical mounting of semiconductor components, the so-called chip and wire bonding (whole-surface connection of the rear-side of the chip on the substrate carrier and production of the electrical connection by means of wire bonded connections) and also flip chip methods are used. These methods allow a partly compact two-dimensional construction based on standard components but do not extend to the third dimension.

The overall system construction which carries the electronic components (e.g. integrated circuits) is intended to be effected on a smaller and smaller space with high-density wiring with the smallest signal losses. The contacting is intended to be undertaken such that thermomechanical forces are absorbed, i.e. that components of differing size and with different thermal coefficients of expansion can be connected to each other in a flexible manner. In order to minimise the electrical connection lengths and at the same time to change over to a compact system construction, a three-dimensional modular architecture which can integrate the most varied of electronic components is required.

To date, for example unhoused electronic circuits are mounted and contacted as an individual component on the substrate carrier (e.g. circuit board) by means of “chip and wire” or wire bonding methods or housed components are mounted on the substrate carrier in general by a soldered connection. This rigid arrangement allows in fact stacking of circuit boards with suitable macroscopic contact connections (e.g. plug connections or the like) but no miniaturised overall construction.

The third dimension and a compact construction can be effected also by very complex technological methods, such as stacking of rigid thinned active Si chips or silicon wafers with through-contactings (through silicon vias). The processes for the through-contacting, the contacting end layers and for the passive circuit elements and also the wiring must be integrated in this case in semiconductor processes (FEOL; BEOL). Thermal stresses are minimised by using materials with very similar or identical coefficients of expansion. Other approaches are TAB, flip chip on flex or flexible bumps, more space being required here.

### SUMMARY OF THE INVENTION

The object of the present invention hence resides in producing a functional unit which enables integration of active and passive electronic components, these being protected mechanically on the one hand and the resulting functional unit having mechanical flexibility at least in regions.

This relates firstly to a functional unit, containing at least one active or passive electronic component, said functional unit being surrounded by at least one flexible dielectric layer and, on the outer side of the functional unit, contacts being provided for contacting the electrical components for the further mounting.

The electronic components are hereby protected mechanically and electrically, on the one hand, by a dielectric layer and, on the other hand, a substrate layer which is also mechanically bendable can be produced by the flexibility of the functional unit, this is particularly advantageous in the case of highly loaded everyday objects.

The method for the production of a functional unit provides that
a) a sacrificial layer is applied on a substrate carrier,
b) this sacrificial layer is provided at least in regions with metallisations, subsequently
c) a dielectric layer is applied whilst leaving the metallization free in regions and
d) the free regions are provided with contacts for electrical connection at least of one active or passive electronic component,
e) after electrical connection to the electronic component, the latter is integrated in a further dielectric layer whilst leaving electrical contacts free, and
f) the sacrificial layer is subsequently removed again.

It is hereby advantageous that a substrate carrier is covered with the sacrificial layer and the construction of the further layers is effected thereafter. These layers concern flexible metallization or flexible dielectric layers. These are applied at least in regions in the surface plane of the functional unit so that a certain flexibility is provided here. A rigid substrate carrier (for example made of silicon or glass) is not retained, which can be disposed less compactly or displays increased risk of breakage in the everyday operation of particularly loaded objects.

The approach according to the invention with respect to a solution therefore resides in the fact that active and passive components are embedded and simultaneously contacted as bare dies (bare chip) in a flexible organic substrate plane. For this purpose, this arrangement is constructed and subsequently removed by means of suitable technological methods (e.g. thin-film technology) on a rigid substrate carrier (e.g. silicon, glass or the like). As a result, a thin flexible organic circuit carrier is produced, with embedded active and passive components which can be connected to form a complete circuit. As a result of a suitable layout of the electrical connection contacting pads and also of suitable connection methods, a three-dimensional construction of a plurality of circuit carriers by means of stacking is possible.

According to the requirements of the system, the number of wiring planes required can vary. A connection contacting on the upper and lower side of the flexible substrate carrier with embedded electronic components is also not always required.

The system can be designed as a flexible or partially flexible substrate layer.

The organic substrate carrier contains embedded electronic components (e.g. electronic active and/or passive circuits (ICs)) which can be connected to each other to form a circuit.

The circuit carrier is provided with external connection contacts, for example all the component connections not requiring to be led out in every case.

The electrical connection planes within one substrate and also the contacting of the electronic components are produced by means of methods of thin-film technology. This can be expanded by using other technologies (e.g. lamination of prestructured substrate planes).

In the case of an embodiment with contacts on both sides, a three-dimensional construction (stacking) with further substrate layers which are configured in a similar manner and can differ in the number of embedded components and wiring levels and layout is possible. For example solder globules or other metallic connection structures serve as connection element between a plurality of individual substrate planes.

A compact electronic system with partial functionality can be produced by connecting together (wiring) a plurality of components and layers.

A free choice of the embedded components (e.g. standard chips, special components . . . ) is possible, which have been prepared in part by further technical processes (e.g. thinning, connection modification or others).

The embedded semiconductor chips are usually used after being thinned.

An extremely compact electronic system or partial system can be produced in this way, which could be further miniaturised only by monolithic integration or more cost-intensive integration technologies.

Components of a different production technology (CMOS, logic, analogue, MEMS etc.) can be combined with this method to form a compact complete circuit. Relative to printed circuit board constructions or rigid substrate constructions made of e.g. ceramic, glass or silicon substrates, the construction has a high degree of miniaturisation, reduces the number of individual process steps required and hence can be switched over to more economically and rapidly by the listed features.

Also electronic partial systems with e.g. components of a small geometry can be produced by means of the approach according to the invention.

The method can be used also for the fan-out IO adaptation of electronic individual components for mounting on other substrate carriers, e.g. printed circuit boards, and is hence an alternative to so-called chip-size packages.

An advantageous development provides that the functional unit is a substrate layer which is flexible or at least flexible in regions. As a result, bending or twisting of the substrate layer in the installed state within an electronic appliance is possible.

A further advantageous development provides that the electronic component is an integrated circuit.

Advantageously, a plurality of active or passive electronic components are connected electrically to each other within one layer of the functional unit. In addition, a layer construction of a plurality of layers can hereby also be provided in the functional unit, at least one active or passive electronic component being disposed in each layer.

It is particularly advantageous that the active or passive electronic components are thinned.

For example silicon components can hereby be produced on one wafer and subsequently be thinned in a grinding process. This thinning has the advantage, on the one hand, that the constructional height of the functional unit can be kept small. On the other hand, a certain flexibility of the components can consequently be obtained. If for example the grinding is implemented until the thickness is in the range of 20 to 50 μm, particularly preferred 15 to 20 μm, a silicon component is bendable within certain limits so that, even with integration of an integrated circuit, the functional unit is bendable in the entire surface plane.

### BRIEF DESCRIPTION OF THE DRAWING

The invention is explained now with reference to a plurality of Figures. There are shown:

Images 1a to 1o illustrate the production of a functional unit according to the invention.

### DETAILED DESCRIPTION OF THE INVENTION

The image sequence 1a to 1o in the following shows the production of a functional unit according to the invention, by way of example. A method for the production of the functional unit is hereby shown, wherein
a) a sacrificial layer (2) is applied on a substrate carrier (1),
b) this sacrificial layer (2) is provided at least in regions with metallisations (3), subsequently
c) a dielectric layer (4) is applied whilst leaving the metallisations (3) free in regions and
d) the free regions are provided with contacts (5) for electrical connection at least of one active or passive electronic component (6),
e) after electrical connection to the electronic component (6), the latter is integrated in a further dielectric layer (7) whilst leaving electrical contacts free, and
f) the sacrificial layer (2) is subsequently removed again.

It can be observed with the invention that the functional unit contains at least one active or passive electronic component, said functional unit being surrounded by at least one flexible dielectric layer and, on the outer side of the functional unit, contacts being provided for contacting the electrical components for the further mounting. A different number of dielectric layers is hereby possible, which can provide a multilayer construction (stacking of a plurality of electronic components) or a corresponding course of the contact layers. For this reason, the sequence shown in image la to lo should therefore be understood merely by way of example.

Image 1a shows a substrate carrier 1 made of silicon or glass. As can be seen in image 1b, a “sacrificial layer” 2 of a few μm thickness, for example a polymer layer made of an adhesive, is applied on the latter. Then copper-based connection contacts or metallisations 3 are applied on this sacrificial layer (see image 1c). Image 1d then shows how a dielectric polymer layer is applied. This can take place for example in the spin-on method in order to apply this layer 4. Regions left free are hereby provided in order to make possible electrical contacting of the connection contacts 3 (see also image 1d).

A wiring plane 5 (likewise for example copper-based) is subsequently provided on the dielectric layer 4 or in the corresponding free region. It can be advantageous that an adhesive layer is applied in advance on the connection contact or the metallisation 3. The state shown in image 1e is hence displayed. Two integrated circuits 6 are subsequently applied on the dielectric layer 4, this hereby concerning thinned integrated circuits 6 with approx. 20 μm (see image 1f).

Image 1g shows how a further dielectric polymer layer 7 is subsequently applied, free regions being provided here for contactings. The second dielectric polymer layer 7 is applied in a deposition process and vias to the first wiring plane (i.e. the wiring plane/the contacts 5) and the contacts of the components (integrated circuit) are opened. The layer 7 is hereby thick enough and planarising so that the components (integrated circuit 6) are completely embedded.

Image 1h then shows the introduction of a second wiring plane or contacts 8 which enables the first wiring plane and the electrical contacting to the integrated circuits 6 via the vias (image 1h).

Image 1i then shows how a third dielectric polymer layer 9 is deposited and the vias to the second wiring plane/contacting layer to the components, in particular to the integrated circuit 6, is opened (image 1i). A third wiring plane or contacts 10 is then deposited if required and connected via the vias to the second wiring plane, as can be seen in image 1j.

Image 1k shows how a fourth dielectric polymer layer/passivation layer 1l is deposited and vias to the third wiring plane 10 are opened.

Image 1l shows an electrical contacting plane 12 which serves as I/O connection metallisation. This is deposited on the upper side of the layer system on the vias of the fourth polymer layer 11 and connected to the third wiring plane/contacts.

Image 1m shows the intermediate product after removing the substrate carrier 1. Image 1n shows the state in which the sacrificial layer 2 is then removed again in addition.

Image 1o shows the end state in which the upper contacts 12 and also the lower connection contacts 3 are provided with contact elements, the present solder drops/solder bumps 13.

The functional unit shown in image 1o can then be coupled electrically to further functional units in the course of production.

Although the invention herein has been described with reference to particular embodiments, it is to be understood that these embodiments are merely illustrative of the principles and applications of the present invention. It is therefore to be understood that numerous modifications may be made to the illustrative embodiments and that other arrangements may be devised without departing from the spirit and scope of the present invention as defined by the appended claims.

1. An apparatus, comprising:
a functional unit, containing at least one active or passive electronic component;
at least one flexible dielectric layer surrounding said functional unit; and
a plurality of contacts, provided on an outer side of the functional unit, for contacting the at least one electrical components for further mounting.

2. The apparatus according to claim 1, wherein the functional unit is a substrate layer which is flexible or at least flexible in regions.

3. The apparatus according to claim 1, wherein the at least one electronic component is an integrated circuit.

4. The apparatus according to claim 1, wherein a plurality of active or passive electronic components are connected within one layer of the functional unit and are electrically conductive with each other.

5. The apparatus according to claim 1, wherein the functional unit has a plurality of layers, at least one active or passive electronic component being disposed in each layer.

6. The apparatus according to claim 1, wherein the at least one active or passive electronic components are thinned.

7. The apparatus according to claim 1, wherein the thickness of the at least one active or passive electrical components is one of: (i) 15 to 100 μm; (ii) 20 to 50 μm; and (iii) 15 to 20 μm.

8. A method for the production of a functional unit, comprising:
applying a sacrificial layer on a substrate carrier;
applying metallizations on the sacrificial layer at least in regions;
applying a dielectric layer whilst leaving the metallizations free in at least some regions;
providing contacts on the free regions for electrical connection to at least one active or passive electronic component;
including the at least one electronic component in a further dielectric layer whilst leaving the electrical contacts free; and
removing the sacrificial layer.
